(19) United States
(12) Patent Application Publication
(10) Pub. No.: US 2008/0309520 A1
(43) Pub. Date: Dec. 18, 2008

(54) COMMUNICATION DEVICE INPUT SYSTEM

(76) Inventor: Kelce S. Wilson, Murphy, TX (US)

Correspondence Address: KELCE WILSON, 1205 TERRACE MILL DRIVE, MURPHY, TX, 75094, US

(21) Appl. No.: 11/764,787

(22) Filed: Jun. 18, 2007

(51) Int. Cl. H03M 11/02

(52) U.S. Cl. 341/22

(57) ABSTRACT

A system is disclosed that enables more rapid entry of text messages in cell phones that use a 12-key keypad. A cursor movement key placed on the side of a device having a numeric keypad enables a user to more quickly and easily and advance the cursor position between letter entries. By placing a cursor movement key in a position that it can be actuated by a different finger than the one in contact with the keypad, a user will be able to type a text message more rapidly when using only a single hand. Providing one or more user-reconfigurable keys on a cellular telephone enables a user to optionally enable a key to perform a desired function or else to be selectively disabled, thereby preventing unintentional input. An embodiment comprises a keypad on a first face and a first cursor movement key on a second face.

### TECHNICAL FIELD

The invention relates generally to communication devices and more particularly, to text entry systems for cellular telephones.

### BACKGROUND

Cellular telephones are often used for sending text messages. However, many lack QWERTY keyboards for fast typing of the messages, relying on the 12-key standard telephone keypad for text entry. Typically, “1” is used for the numeral “1” and punctuation, “2” is used for the letters “a”, “b” and “c”, “*” is used for capitalization, “0” is used for the number zero, and “#” is used for blank spaces between words. The remaining letters are divided up between “3” though “9”, typically with 3 letters per key, although “7” and “9” each have 4 letters. A typical cellular telephone will also have cursor movement keys, such as cursor advance, backspace without delete, backspace with delete, up and down. Other schemes can also be used.

To type a word, a user selects the key representing a desired letter and presses the key to cycle through the options until the desired letter is brought up. For example, to select the letter “k” a user presses “5” twice and then either presses a different key or else waits for a timer to expire. That is, the letter “k” is not finally entered into the text field merely by pressing “5” twice, but rather by pressing “5” twice and then by taking a second action selected from the two options of waiting out a timer and pressing a different key.

Pressing a different key is a natural second action, if the following desired letter is assigned to a different key. However, if the following desired letter is assigned to the same key, the user has some choices: (1) wait for the timer to expire, (2) press a cursor advance key to advance the cursor to the next position in the text field, or (3) press a different number key and then delete the surplus character. For example, to send a text message to one's mother, addressing her at the beginning of the message with “Mom” might require the user to press “6”, wait, press “666”, wait again, and then press “6”. For some mothers, this may be quite appropriate, although not for mine. Thus, to type in a simple, 3-letter word, the user has to either wait for two time-out events, or press the cursor advance key twice.

Pressing the cursor advance key between letter selections is not a problem if someone is composing a text message with both hands. However, if a user is driving while drinking a soda, eating a burger, playing with the radio, and checking her makeup in the rear view mirror, all during an argument with a passenger in the car, only one hand is typically available for composing a text message on a cellular telephone. Thus, the user will typically attempt to hold the cellular telephone in one hand and type the message the thumb of the hand holding the cellular telephone. The user having to move her thumb off of the key, to the cursor advance and then back, takes time as well as introduces the possibility of striking the incorrect key.

### SUMMARY

A cursor movement key placed on the side of a device having a numeric keypad enables a user to more quickly and easily and advance the cursor position between letter entries. By placing a cursor movement key in a position that it can be actuated by a different finger than the one in contact with the keypad, a user will be able to type a text message more rapidly when using only a single hand. Providing one or more user-reconfigurable keys on a cellular telephone enables a user to optionally enable a key to perform a desired function or else to be selectively disabled, thereby preventing unintentional input.

Embodiments of a communication device comprise a keypad on a first face of the device and a first cursor movement key on a second face of the device, wherein the second face is adjacent to the first face. In some embodiments, the communication device comprises a cellular telephone with a 12-key keypad, and the first cursor movement key comprises a cursor advance key. However, in some embodiments, the first cursor movement key is configured to be selectively disabled, thereby preventing unintentional input. The first cursor movement key may be used for cursor control concurrently with one of a plurality of cursor keys on the first face, in some embodiments. Some embodiments may further have one or more additional cursor movement keys, optionally located on different faces of the communication device. In some embodiments, the cursor movement keys are user-reconfigurable keys that can be selectively enabled to act as cursor movement keys, or may, in some circumstances, be configured to act as different inputs.

The foregoing has outlined the features and technical advantages of the invention in order that the description that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the invention.

### BRIEF DESCRIPTION OF THE DRAWINGS

For a more complete understanding of the present invention, reference is now made to the following descriptions taken in conjunction with the accompanying drawings, in which:

FIG. 1 illustrates an embodiment of a communication device with an improved input system;

FIG. 2 illustrates another view of the communication device of FIG. 1; and

FIG. 3 illustrates another embodiment of a communication device with an improved input system.

### DETAILED DESCRIPTION

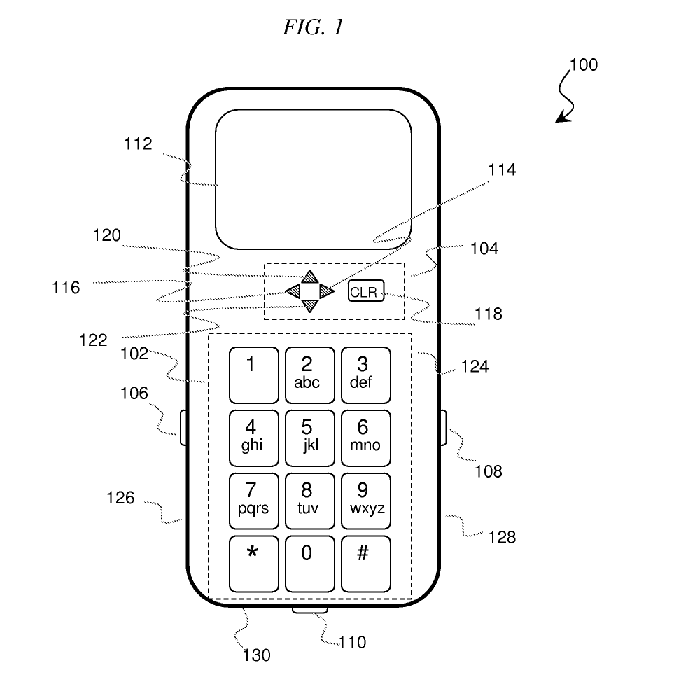

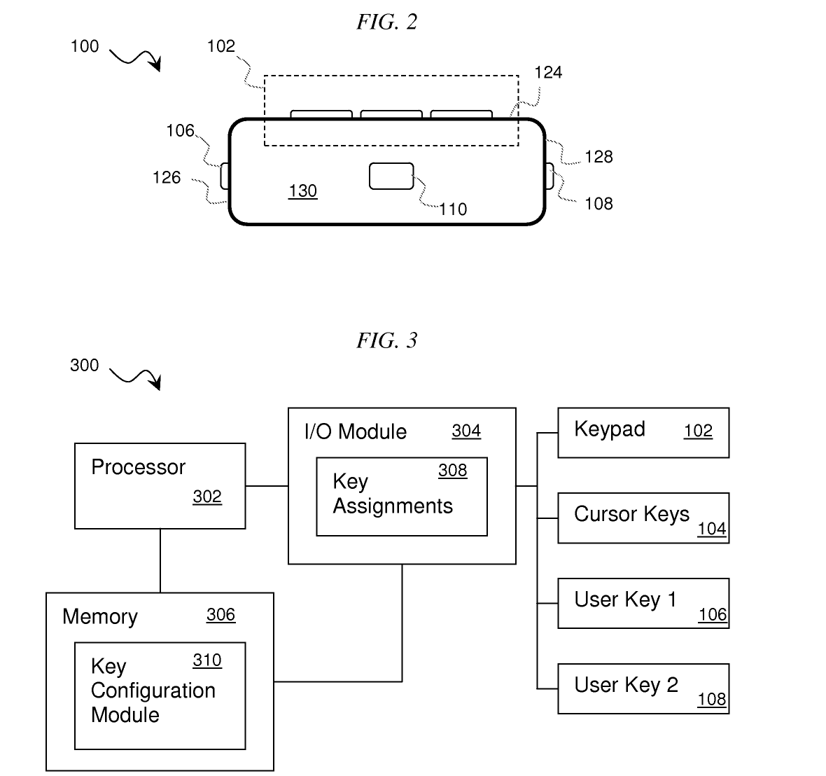

FIGS. 1 and 2 illustrate an embodiment of a communication device 100 with an improved input system. Although FIGS. 1 and 2 illustrate an improved input system for a cellular telephone, the improved input system is not limited to use with only cellular telephones. Other communication devices, including personal digital assistants (PDAs) and Blackberrys may also take advantage of the improved input system. FIGS. 1 and 2 show communication device 100 from different views.

Communication device 100 comprises a keypad 102, cursor keys 104, a first cursor movement key 106, a second cursor movement key 108, a third cursor movement key 110, and a display 112. In the illustrated embodiment, keypad 102 comprises a 12-key keypad with numbers 0-9 and keys for an asterisk and a pound sign. It should be understood, however, that alternative keypad configurations may be used, including keypads with a greater or lesser number of keys. Cursor keys 104 comprises cursor advance key 114, cursor backspace without delete key 116, cursor backspace with delete key 118, cursor up key 120, and cursor down key 122.

In the illustrated embodiment, at least one of first cursor movement key 106, second cursor movement key 108, and third cursor movement key 110 is configured to advance a cursor position during text entry into communication device 100. It should be understood that, while three keys are illustrated, a greater or lesser numbers of cursor movement keys may be used. For example, some embodiments may comprise a single cursor movement key, either key 106 or key 108, and other embodiments may comprise two cursor movement keys, such as both keys 106 and 108. Further, it should be understood that while at least one of keys 106, 108, 110 may be configured to act as a cursor advance key in some embodiments, other cursor movement may be also controlled by one of keys 106, 108, 110 in some embodiments.

Four faces of communication device 100 are labeled in FIG. 1. Keypad 102 is on a first face 124. First cursor movement key 106 is on a second face 126, which is adjacent to first face 124. Second cursor movement key 108 is on a third face 128, which is also adjacent to first face 124. Third cursor movement key 110 is on a fourth face 130, which is also adjacent to first face 124. In the illustrated embodiment, communication device 100 is shown to have approximately rectangular cross sections, such that first face 124 is approximately perpendicular to second face 126, third face 128, and fourth face 130. As illustrated, second face 126 is opposite third face 128.

Communication device 100 is configured to be held and in and used by a single typical, adult hand, such that a user can press any key on keypad 102 with the thumb of the hand holding communication device 100, and actuate one of first cursor movement key 106, second cursor movement key 108, or third cursor movement key 110 with another finger of the same hand. Some embodiments using two keys, for example keys 106 and 108, can be used in either a left-handed or a right-handed mode. However, if both keys 106 and 108 are simultaneously enabled to move the cursor, the user may unintentionally actuate one of them. Therefore, in some embodiments, at least one of keys 106, 108 and 110 is configured to be selectively disabled to prevent unintentional input that may accidentally move the cursor.

Cursor movement keys 106, 108 and 110 may be used concurrently with cursor keys 104, or in place of cursor keys 104. For example, some embodiments allow a user to advance the cursor by actuating either comprises cursor advance key 114 or first cursor movement key 106. Some embodiments may eliminate cursor advance key 114 in cursor keys 104, since a cursor advance function is already provided by one of cursor movement keys 106, 108 or 110.

In operation, a user may configure communication device 100 for left-handed or right-handed operation by selectively enabling either first cursor movement key 106 or second cursor movement key 108, and selectively disabling the other. The user may then hold communication device 100 in a single hand, enter select from keypad 102 with the thumb of that hand, and advance the cursor between immediately subsequent letter selections by actuating either first cursor movement key 106 or second cursor movement key 108 with a finger. The user may control the cursor movement, thus avoiding the need to wait for a timer to expire or to remove the thumb from keypad 102. This feature enables more rapid and accurate inputting of text when subsequent letters in the text are selected by pressing the same key.

In some embodiments, the cursor movement keys 106, 108 and 110 are user-reconfigurable keys that can be selectively enabled to act as cursor movement keys, or may, in some circumstances, be configured to act as different inputs other than cursor control. FIG. 3 illustrates another embodiment of a communication device 300 with an improved input system that enables cursor movement keys 106 and 108 to be selectively enabled, selectively disabled, or selectively assigned to a different function of user input other than cursor movement or control.

Communication device 300 comprises a processor 302 coupled to an input output (I/O) module 304 and a memory 306. 1/0 module 304 is coupled to keypad 102, cursor keys 104, user-reconfigurable key 106 and user-reconfigurable key 108. User-reconfigurable key 106 and user-reconfigurable key 108 are configured to be selectively enabled as cursor movement keys, including cursor advance keys by referencing key assignments 308 in I/O module 304. Processor 302 sets key assignments 308 using user input from keypad 102 and data and instructions in key configuration module 310 in memory 306. For example, in some embodiments, user-reconfigurable key 106 could be enabled to act as a cursor advance key, while user-reconfigurable key 108 is enabled to act as a telephone ringer volume control.

Although the present invention and its advantages have been described, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An device comprising:
a keypad on a first face of the device, wherein the device is configured to be held in a single typical, adult hand; and
a first cursor movement key on a second face of the device.

2. The device of claim 1 wherein the device comprises a cellular telephone.

3. The device of claim 1 wherein the keypad comprises a 12-key keypad.

4. The device of claim 1 wherein the first cursor movement key comprises a cursor advance key.

5. The device of claim 1 wherein the first cursor movement key is configured to be selectively disabled, thereby preventing unintentional input.

6. The device of claim 1 wherein the first cursor movement key is configured to be actuated by a finger of the hand while the hand is holding the device and a thumb of the hand is in contact with the keypad.

7. The device of claim 1 further comprising:
a plurality of cursor keys on the first face.

8. The device of claim 1 further comprising:
a second cursor movement key on a third face of the device, wherein the third face is adjacent to the first face.

9. The device of claim 8 wherein the third face is opposite the second face.

10. The device of claim 8 wherein the device is configured to enable a user to select a single one of either the first cursor movement key or the second cursor movement key to be used concurrently with the keypad, such that the other one of the first cursor movement key and the second cursor movement key is disabled.

11. The device of claim 1 wherein the second face is adjacent to the first face and is oriented approximately perpendicular to the first face.

12. A cellular telephone comprising:
a keypad on a first face of the cellular telephone; and
a first user-reconfigurable key on a second face of the device.

13. The cellular telephone of claim 12 wherein the first user-reconfigurable key is configured to be selectively enabled as a cursor movement key.

14. The cellular telephone of claim 12 wherein the second face is adjacent to the first face and is oriented approximately perpendicular to the first face.

15. The cellular telephone of claim 12 wherein the first user-reconfigurable key is configured to be actuated by a finger of the hand while the hand is holding the cellular telephone and a thumb of the hand is in contact with the keypad.

16. The cellular telephone of claim 12 further comprising:
a second user-reconfigurable key on a third face of the device, wherein the third face is adjacent to the first face, oriented approximately perpendicular to the first face, and opposite the second face.

17. A method of inputting text into a cellular telephone, the method comprising:
selecting a first letter from a keypad, wherein the keypad is on a first face of the cellular telephone and wherein selecting a letter comprises pressing a first key of the keypad; and
actuating a first cursor movement key, wherein the first cursor movement key is on a second face of the cellular telephone, wherein the second face is adjacent to the first face, and wherein the second face is oriented approximately perpendicular to the first face.

18. The method of claim 17 further comprising:
selecting a second letter from the keypad immediately after the actuation of the first cursor movement key, wherein the actuation of the first cursor movement key occurs immediately after the selection of the first letter, and wherein selecting a second letter comprises pressing the first key.

19. The method of claim 17 further comprising:
selectively enabling the first cursor movement key.

20. The method of claim 17 further comprising:
selectively disabling a second cursor movement key, wherein the second cursor movement key is on a third face of the cellular telephone, wherein the third face is adjacent to the first face, and wherein the third face is oriented approximately perpendicular to the first face.
